(19) United States
(12) Patent Application Publication
(10) Pub. No.: US 2010/0109915 A1
(43) Pub. Date: May 6, 2010

(54) Rapid Typing System for a Hand-held Electronic Device

(76) Inventor: John E. Scarboro, Lafayette, CO (US)

Correspondence Address: ARNOLD & PORTER LLP;ATTN: IP DOCKETING DEPT., 555 TWELFTH STREET, N.W., WASHINGTON, DC, 20004-1206, US

(21) Appl. No.: 12/263,087

(22) Filed: Oct. 31, 2008

(51) Int. Cl. H03M 11/00

(52) U.S. Cl. 341/20

(57) ABSTRACT

An ergonomic system for placing primary inputs on the back, bottom, or sides of an electronic device. By way of example, the system places two primary inputs at each finger position and makes use of a ‘dual-subset’ chordal keyboard input design that effectively doubles the number of available inputs. The result is a system in which the operator's fingers never need to move from their positions on the backside of the device yet the operator can instantly access character/function sets as large as a complete alphabet, allowing for rapid typing speed and extensive device control, even on a small hand-held electronic device.

### BACKGROUND OF INVENTION

Since the inception of the computer there has been a constant drive to produce smaller and smaller models. However, miniaturization to the extent of hand-held models has proved problematic despite the successful shrinking of processors and data storage. The screen and the keyboard have been forced to fight for front-side real estate, causing inventors to try combining the two, in the tablet model, or shrinking both to toy-like proportions in the thumb keyboard model. Neither of these methods come close to replicating the typing speed of the full-size QWERTY model and the QWERTY system is so entrenched in the mind of the public that there has never been great success in convincing them to adopt a new system which is designed to shrink, i.e. one with fewer keys. However, as in the case of cell phone text messaging, the public has proved itself to be incredibly adaptive to a new system when there is cause.

So-called chordal keyboards are keyboards which produce characters when combinations, or chords, of keys are struck in tandem as opposed to the traditional ‘one key equals one character’ QWERTY model. Chordal keyboards would appear to be the perfect solution to miniaturization as many less keys are required to produce a desirable complete character set, such as the English alphabet. However chordal systems do not appear to have achieved widespread mainstream success because the learning curve is steep and the idea of striking multiple keys can be visually and conceptually frustrating. However, the fact is that a chordal keyboard system, when committed to muscle-memory, can be even faster than its QWERTY counterpart, which takes some time to learn in its own right.

The problem with the chordal systems is that the initial hurdle of visual and conceptual unfamiliarity and complexity bars most potential operators from ever attempting to familiarize themselves with them. Therefore any chordal keyboard device wishing to cross over into the realm of general public acceptance must take great steps to make itself easy to understand, visually simple, and instantly usable. That is the first goal of the present invention.

There have been devices including inputs on the back, bottom, or sides of a hand-held computer or keyboard replacement device: U.S. Pat. No. 6,107,988, U.S. Pat. No. 6,297,752, U.S. Pat. No. 6,939,066, and U.S. Published Application No. 2007/0216640, among others.

Examples of chordal (a.k.a. chord or chording) keyboards are reflected in the following: U.S. Pat. No. 4,042,777, U.S. Pat. No. 4,442,506, U.S. Pat. No. 5,189,416, U.S. Pat. No. 6,542,091, U.S. Pat. No. 7,387,457, and U.S. Pat. No. 7,340,171 (Universal Input Device or UID) among many others.

Examples of patents employing both chordal systems and inputs on multiple surfaces are: U.S. Pat. No. 4,467,321, U.S. Pat. No. 4,655,621, U.S. Pat. No. 5,267,181, U.S. Pat. No. 5,432,510, U.S. Pat. No. 5,515,305, U.S. Pat. No. 5,984,548, U.S. Pat. No. 7,218,313, U.S. Published Application No. 2006/0202865, and U.S. Published Application No. 2004/028681 (Back Side Keyboard or BSK).

Several examples of what could be considered chordal keys that exist on current devices are the “shift”, “control”, and “alt” keys on the QWERTY keyboard and the extended functions on scientific calculators. These have “made it” because they are conceptually and mechanically simple: one button which changes the function of all the others. The present invention uses, at its core, this kind of simplicity and thereby distinguishes itself from all other chordal systems.

Most chordal keyboards can be seen as having primary input keys, which relate to specific characters or functions, and selector input keys, which change the character/function subset denoted by the primary input keys. In all chordal keyboards aside from the present invention, the chordal systems utilize a relatively high number of selector keys to obtain a high number of character/function subsets. For instance, in the hand-held embodiment of the UID, there are four primary input keys. In order to achieve a character set of, say, 32 characters, eight character subsets, and therefore eight selectors inputs, are required (the exact number is variable on the UID). Thus, operators must continually navigate their way through eight character subsets in order to type a paragraph. Even in a relatively less complex system, such as the chordal embodiment of the BSK which utilizes ten primary input keys and four selector keys, the operator is required to navigate through four different subsets, undoubtedly hunting through subset after subset for each subsequent character.

The preferred embodiments of the present invention simplify the navigation process by having only one selector key in any given character set and therefore only two subsets to move back and forth between at any time. This requires at least 13 primary input keys for the English alphabet—one preferred embodiment has 16.

### SUMMARY OF ASPECTS OF THE PREFERRED EMBODIMENT

Illustrative embodiments of the present invention provide a system of inputs which allows for rapid typing speed, which is ergonomic, and which lends itself to miniaturization or placement on handheld devices.

Illustrative embodiments of the present invention also provide a system of inputs which are capable of delivering every input available on the QWERTY keyboard, including alphabet characters, numeral characters, symbols, control functions, hot-keys, navigational commands, and also could deliver a potentially limitless capacity for other inputs, limited only by the device's memory capabilities.

Preferred embodiments of the present invention also provide a system of inputs which delivers the inputs in discreet sets designed for specific purposes.

Preferred embodiments of the present invention also provide a system of inputs which could be programmable with regard to the visual guides and the specific content of sets and lay-out of set-menus, allowing an operator to tailor the device to their specific needs and purposes.

In accordance with the present invention, a system is provided for placing inputs on any electronic device. This system comprises a plurality of primary inputs placed on the back, bottom, or sides of the device and a single selector input placed elsewhere on the device. The majority of the primary inputs are paired into twos, the pairs aligning with the positions of the tips of the operator's fingers as they reach around to the back, bottom, or sides of the device. In the preferred embodiment, the single selector input is aligned with one of the operator's thumbs and the primary input pairs are achieved by 3-position momentary rocker switches (the central position being neutral or off).

Each primary input, when activated, provides either a character (such as a letter [W], number [7], or symbol [!]), a function (such as a device control [open], navigation [page up] or software command [select all]), or any other element required by the device (mathematical formula, print spooler, flow chart, etc.). These primary input designations are grouped into sets (such as an English alphabet set).

Complete sets of primary input designations are not available to the operator all at one time. Rather, complete sets are divided into two sister subsets that the operator toggles between during normal usage. Therefore, the number of designations available in a complete set is double the number of primary inputs. For example, a complete English alphabet set [A-Z] can be divided into the two subsets [A-M] and [N-Z]. The selector input toggles between the two subsets. This configuration is an example of a ‘dual-subset chordal input system’.

Primary input guides, visual representations of the designations of the primary inputs, can be made to appear on the device's screen or monitor. These guides mirror (exactly or loosely) the positions of the primary inputs on the reverse side and change instantly to reflect the current designations of the primary inputs.

In addition, the input system may also incorporate hot sets and set menus that allow the operator to switch between various complete sets of designations. An operator typing in English, for instance, would likely need to quickly switch between an English alphabet set, a punctuation set, a number set, and a text navigation set at will, as well as other sets relating to their specific project.

Finally, the system is rounded out by the inclusion of character/function manipulation inputs. These are inputs that potentially apply to any and every character or function set, for instance [space bar] or [undo].

### BRIEF DESCRIPTION OF FIGURES

FIG. 1 depicts a 3-position momentary rocker switch.

FIG. 2 depicts eight 3-position momentary rocker switches placed on the back of a generic hand-held electronic device.

FIG. 3 and FIG. 4 depict the preferred embodiment of the input system applied to a hand-held electronic device such as a PDA. FIG. 3 depicts the front and FIG. 4 depicts the back.

FIG. 5 depicts the preferred embodiment of the input system applied to a cellular phone.

FIG. 6 depicts the preferred embodiment of the input system applied to a touch-screen cellular phone.

FIG. 7 depicts a basic English alphabet set, alphabetically arranged.

FIGS. 8(a), 8(b), 8(c) and 8(d) depict four different possible arrangements for an English alphabet set.

FIG. 9 depicts a potential text navigation set.

FIG. 10 depicts a typical set menu.

FIG. 11 depicts the primary input guides being displayed on the screen of the device.

FIG. 12 depicts a flowchart outlining the event sequence of the basic inputs in the preferred embodiment.

FIG. 13 depicts the components of a device including inputs in accordance with an embodiment of the present invention.

FIG. 14 depicts a ‘half-set’ for controlling a trackball.

FIG. 15 depicts a stripped-down version of the preferred embodiment of the input system applied to vehicle controls.

FIG. 16 depicts the preferred embodiment of the input system applied to a keyboard-replacement controller.

FIG. 17 depicts the preferred embodiment of the input system applied to a monitor-only unit.

FIGS. 18, 19, and 20 depict potential sets of primary input designations when the present invention is applied to a production machine.

### DETAILED DESCRIPTION OF PREFERRED EMBODIMENTS

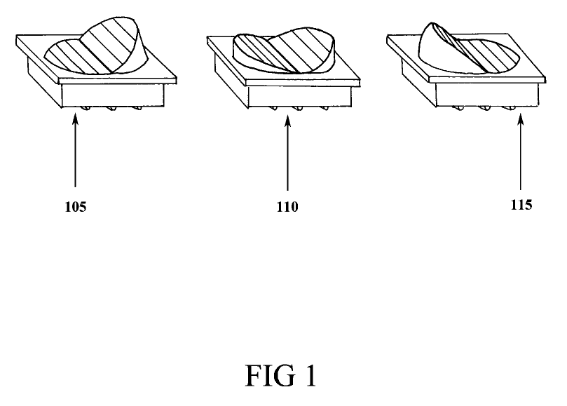

FIG. 1 depicts a 3-position momentary rocker switch, the input device used to achieve each pair of backside primary inputs in the preferred embodiment of the present invention. Both the left side position 105 and the right side position 115 correspond to one of the inputs within the input pair. The central position of the rocker switch 110 is the neutral or off position, providing no input signal. When either the left side position 105 or the right side position 115 is released, the switch springs back to the central position 110.

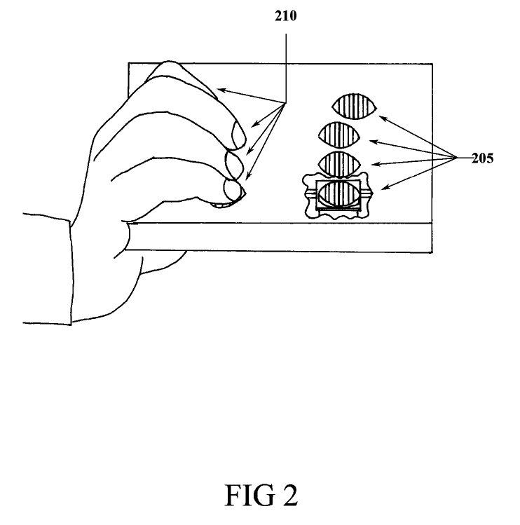

FIG. 2 depicts eight 3-position momentary rocker switches 205 (the number of rocker switches utilized in the preferred embodiment), placed on the back of a generic hand-held electronic device. The switches align with the tips of the operator's fingers 210 as they reach around to the back of the device. The use of the rocker switches allows for the operator to never need move his or her fingers from the switches and grope for inputs on the backside. This also provides ergonomic economy of movement, putting less strain on the forearm flexors, the muscles which, when inflamed, cause carpal tunnel syndrome (in fact, the overall design of the device, with its inputs on the backside, places the forearm flexors in a natural, relaxed position—in which they are strongest and least prone to injury through repetitive stress.)

However, the primary inputs and all of the inputs on the device, in other embodiments, could be implemented as rocker switches, buttons, keys, roller switches, heat or pressure sensitive pads, multi-directional buttons or switches, multi-level buttons, multi-positional switches, toggle switches, touch-screen inputs, or other means.

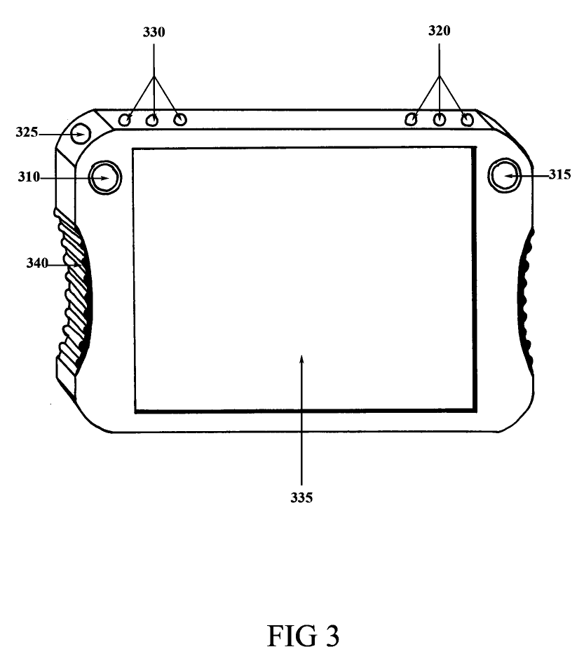

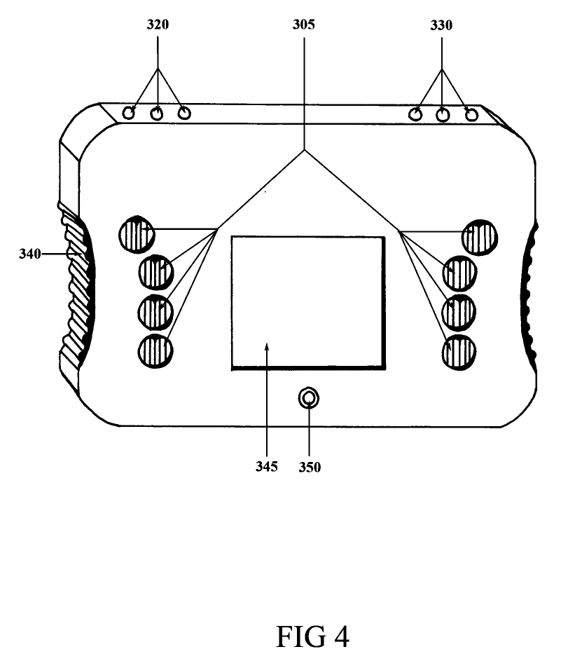

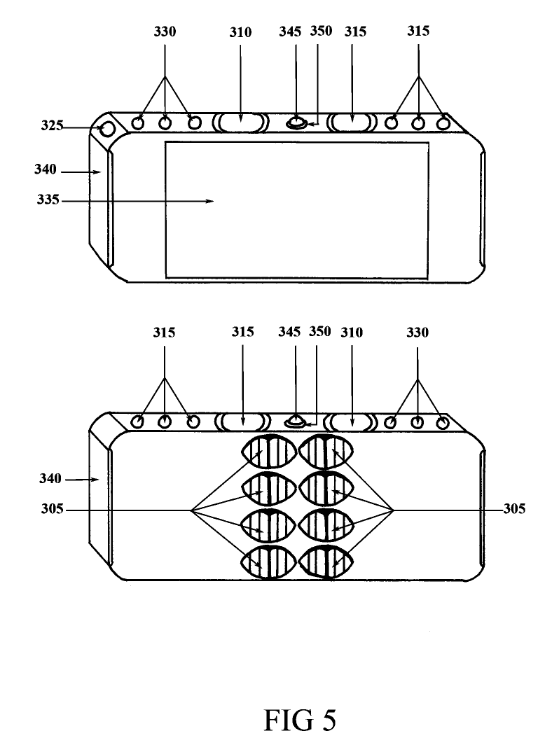

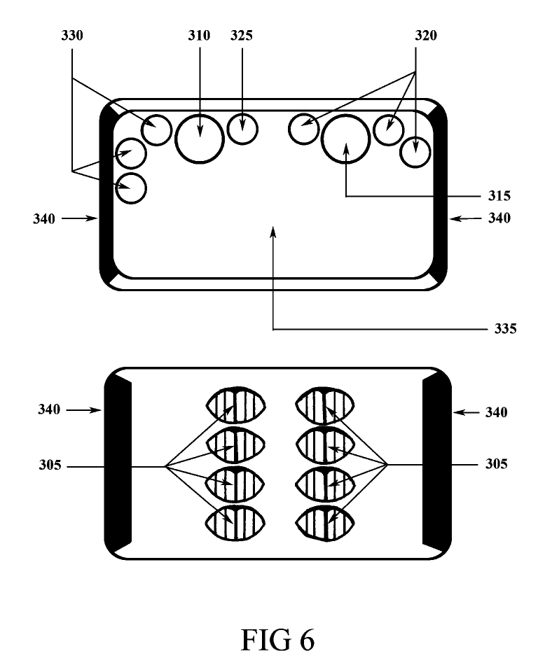

FIG. 3 and FIG. 4 depict the preferred embodiment of the input system applied to a hand-held electronic device such as a PDA, while FIG. 5 depicts the preferred embodiment of the input system applied to a cellular phone and FIG. 6 depicts the preferred embodiment of the input system applied to a touch-screen cellular phone.

In the preferred embodiment, there are sixteen primary inputs on the backside of the device divided into eight pairs of inputs. The pairs are achieved by eight 3-position momentary rocker switches 305 that align with the tips of the operator's fingers as they reach around to the back of the device. The selector input 310 is positioned on the front or top of the device, in alignment with the operator's left thumb. In alignment with the right thumb is the primary right-side supplementary input 315 and available to the right thumb are additional right-side supplementary inputs 320. Available to the left thumb are the guide input 325 (a supplementary input) and several additional left-side supplementary inputs 330. Note that in the touch-screen phone version (FIG. 6) the selector input 310 and all of the supplementary inputs 315-330 are on-screen touch-screen inputs.

The screen 335 takes up almost the entire front side of the device. Rubber grips 340 on the sides of the device help to increase friction against the operator's palms as they hold up the device. All of the fingers also apply light pressure on the rocker switches 305 while in the central off position to assist in holding up the device. The thumbs also apply holding pressure with the eminences of their second joints, well away from the thumb-aligned inputs 310, 315, 320, 325, 330 that are available to be manipulated by their tips.

A trackball 345 and trackball input 350 are placed on the back of the hand-held device and top of the cellular phone. However, with a touch-screen cellular phone, a trackball may be unnecessary.

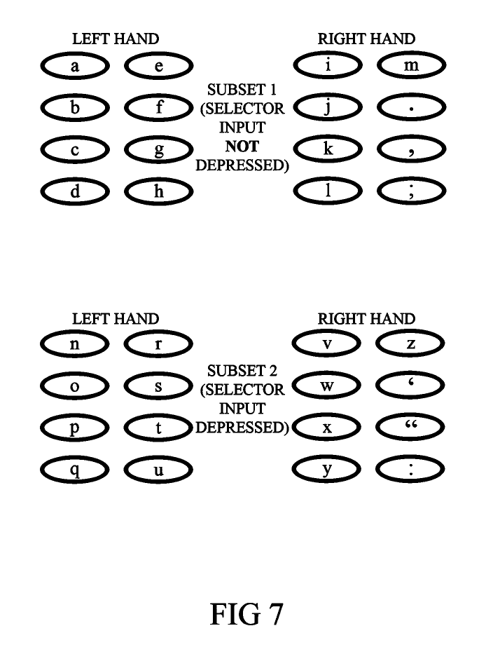

FIG. 7 depicts a basic English alphabet set, alphabetically arranged, split into the two sister subsets, 7a and 7b, which together make up the entire set. 7a shows the designations of the primary inputs 305 when the selector input 310 is not depressed and 7b shows the designations of the primary inputs 305 when the selector input 310 is depressed.

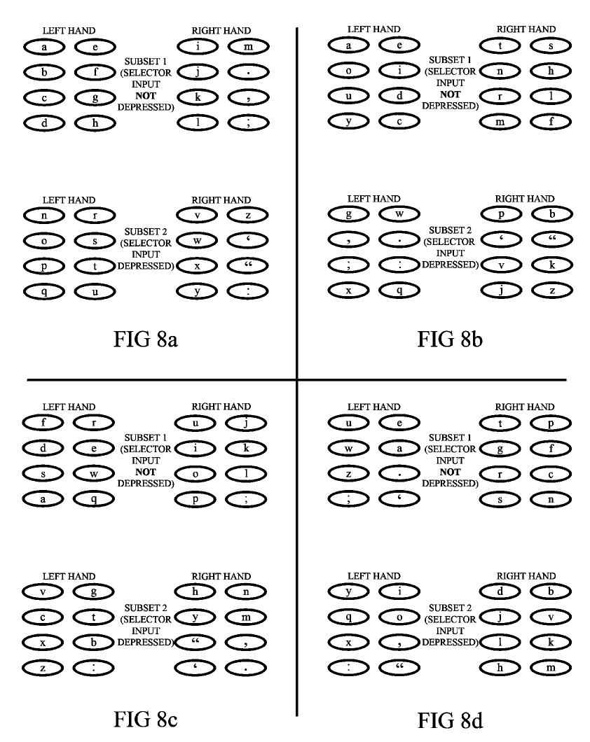

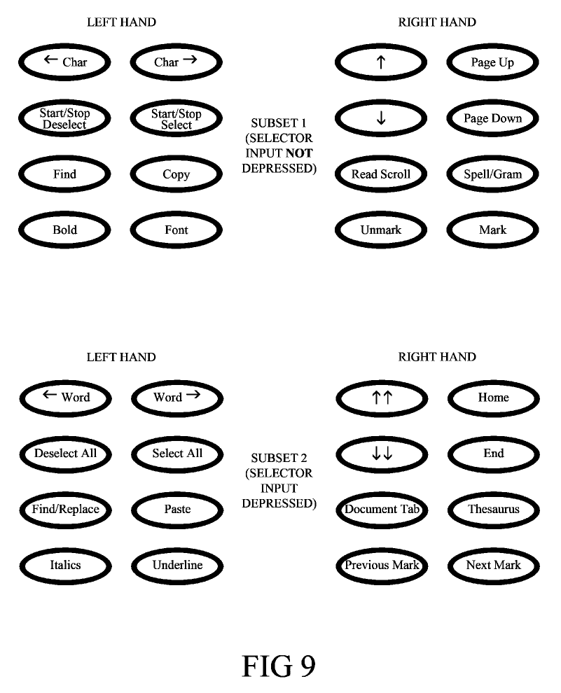

FIGS. 8(a)-8(d) and 9 depict examples of typical sets that could be present in the system. FIG. 8 depicts four different possible arrangements in FIGS. 8(a), 8(b), 8(c), and 8(d), for an English alphabet set. 8(a) is arranged alphabetically. 8(b) is arranged according to how frequently each letter occurs in typing, with the more frequent letters assigned to the stronger, more dominant fingers. 8(c) is arranged to mimic the QWERTY keyboard, with the letters being manipulated by the same fingers that manipulate them on the QWERTY keyboard. 8(d) is arranged according to a system of paired phonemes. For instance, [B] and [P] are both formed by the same lip construction, however [B] is voiced while [P] is unvoiced. [B] and [P] are designated by the same primary input 305 in different subsets. FIG. 9 depicts a potential text navigation set. The specific arrangement of any set is programmable through the programming set.

Available sets could include (but are not limited to): native and foreign language alphabet sets, number sets, symbol sets, text navigation sets, book/newspaper navigation sets, map navigation sets, scientific calculation sets, command sets, hot-key sets, programming sets, cellular phone control and call list navigation sets, 2-D, 3-D, or 4-D navigational sets, code programming sets, copy-editing sets, software control sets, game control sets, formula sets, computer navigation sets, machine control sets, artistic use sets, television control sets, camera and video camera control sets, sound system control sets, security system control sets, stock and bond trading and management sets, company management and workflow sets, electric grid (household or company) control sets, etc. In fact any computer, machine, system, or software could theoretically be controlled by this input system.

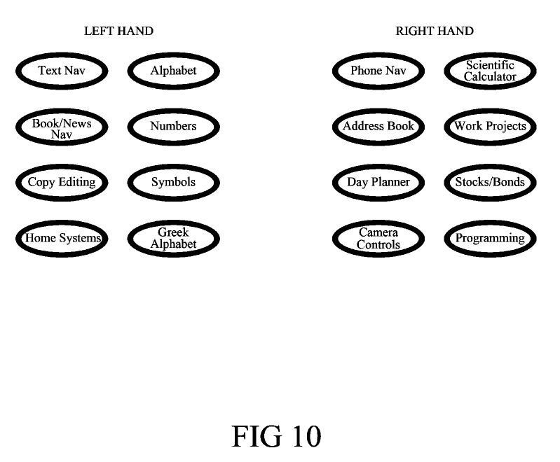

FIG. 10 depicts a typical set menu, in this case the starting set menu for a typical operator. The left-side supplementary inputs 330 consist of a set-menu input and hot-set inputs. The set-menu input 330 turns the primary inputs 305 into a menu of sets, or set menu. This allows the operator to change sets almost instantaneously by keying two inputs: the set menu input 330 and then the primary input 305 assigned to the desired set. This provides for an ample 32 character and/or function sets in the preferred embodiment having 16 primary inputs 305. The hot-set inputs 330 are instant links to other sets typically used in conjunction with the currently selected set.

If the operator required more sets than available in a standard set menu, the bottom two primary inputs 305 of the right hand (or whichever inputs the operator chose) could become set-menu-toggle inputs that would toggle through set menu after set menu, adding another 30 sets with each further menu. If, in some extreme case such as a device which could produce all of the Chinese characters, the operator required even more sets than the set menu toggle inputs could practically provide, the set menu input could produce a ‘meta-set menu’ or a menu of set menus. In this case, each primary input 305 would represent an entire set menu in itself, providing for 1,024 sets with relative ease, or 32,768 characters and/or functions. If, in some incredible circumstance, more sets were required, the meta-set menu could incorporate set menu toggle inputs to increase the number of sets arithmetically, or even a meta-meta-set (and so on) to increase its capabilities exponentially.

Another potential, more realistic, use of the meta-set menu would be for the logical organization of sets. For instance, a scientist or engineer using the device primarily to generate formulae might wish to group the formula sets according to particular problems or projects. Certain formulae might even be redundant in several sets or sets might be redundant in several set menus, and the set menus within the meta-set menu could be labeled according to the project or type of project they relate to.

Finally, a particular set menu might actually contain an assortment of functions, sets, and meta-sets as its set components. For instance, a set designed to navigate a computer's operating system would likely have, in its starting set, functions such as [back], [search], [close], etc., sets such as those mimicking ‘drop-down menus,’ i.e. [file], [tools], etc., and meta-sets, such as the [C: drive], which would include meta-set upon meta-set within itself as the operator navigated through the computer's folders and files. This type of set configuration comes pre-programmed in the most logical and straightforward manner for the novice operator but is also programmable to suit the specific requirements of the experienced operator. Software control sets relating to specific software programs manifest upon entering the corresponding program. All set components are programmable via the programming set.

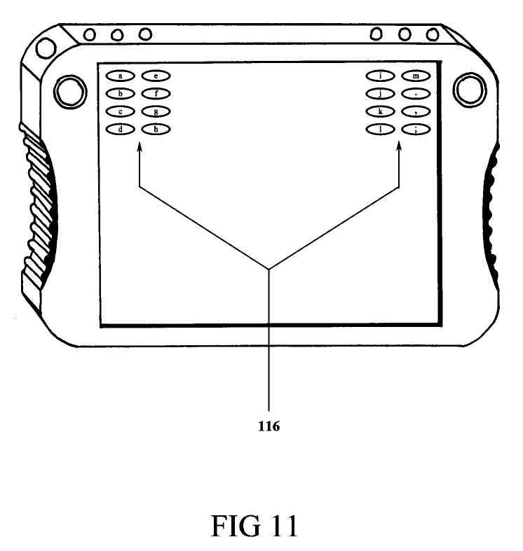

FIG. 11 depicts the primary input guides 1105 being displayed on the screen of the device. The primary input guides 1105 are visual on-screen representations of the character, function, or set designated by each primary input 305. The primary input guides 1105 mirror, on the front-side screen of the device, the physical positions of the primary inputs 305 on the back-side. This allows for excellent reinforcement of hand-eye coordination when training the fingers to type and assists the operator in the skillful manipulation of any character or function set and subset, as well as providing a tool for navigating through the sets, subsets, and set menus.

Guides for the right-side supplementary inputs 315, 320 are also provided. Right-side supplementary inputs 315, 320 provide manipulations that apply to every possible character set, such as [space bar], [return], [delete], [tab], [capitalize], [caps lock], etc. In non-character sets they represent manipulations that apply to most non-character sets, such as [enter], [undo], [re-do], [escape], etc. In the preferred embodiment, these are placed in alignment with or accessible to the right thumb.

The primary input guides 1105 are turned on and off or set to display the right-side supplementary inputs 315, 320 using the guide input 325. The guides 1105 can be moved from their home positions to accommodate the specific needs of the operator or work around the rest of the screen display. The size of the guides 1105 relative to the screen is also programmable. The guides 1105 can have full-length descriptors and also abbreviated versions to save room on the screen.

Optionally, individual guides 1105 can ‘light up’ or reverse colors in response to their input being keyed to further reinforce hand-eye coordination. Finally, the operator can decide whether or not to have a ‘grayed out’ or ‘shadow guides’ representation of the appearing subset's sister subset. This last would assist operators, especially novices, in the constant understanding of the entire scope of any one set. All of these customized settings are available through the programming set.

Alternatively, or in addition to visual guides 1105, auditory guides could be supplied that provide auditory reinforcement such as one or more speakers that announces the character or function designated by a primary input 305 when it is keyed.

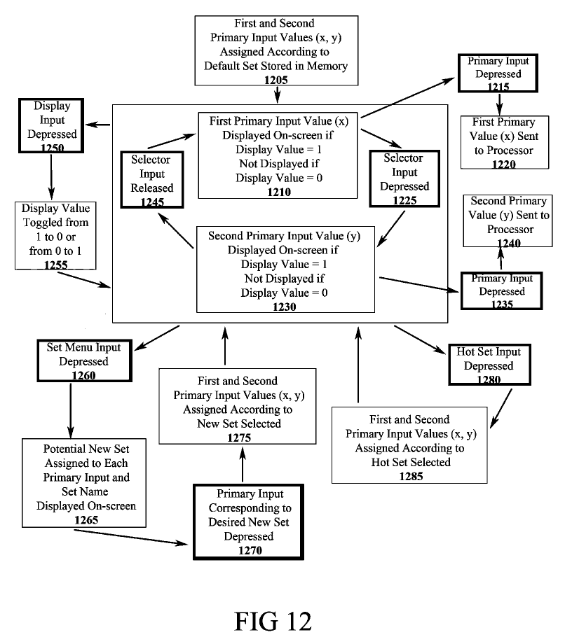

FIG. 12 depicts a flowchart outlining the event sequence of the basic inputs in the preferred embodiment, these basic inputs being the primary inputs 305, the selector input 310, the guide input 325, the set menu input 330, and the hot set inputs 330. These inputs all relate to the primary input values, a.k.a. the set of characters or functions sent to a processor of the device when a primary input 305 is keyed. The first primary input values (PIV's) make up the first subset of any set and the second PIV's make up the second subset of any set.

When the device is initially turned on, the first and second PIV's are assigned according to the default set stored in the device's memory 1205. The default set is programmable via the programming set. If the display value is set to equal 1, representations of the first PIV's are displayed on-screen to show the operator which PIV's correspond to which primary inputs (if the display value is set to equal 0, the representations are not displayed) 1210. When a primary input is keyed 1215, the corresponding first PIV is sent to the device's main processor in the form of a character or function 1220. When the selector input is depressed 1225, representations of the second PIV's are displayed on-screen if the display value is set to equal 1 1230. Now when the primary input is keyed 1235 (and the selector input is still depressed), the corresponding second PIV is sent to the device's main processor in the form of a character or function 1240. When the selector input is released, representations of the first PIV's return to the screen 1245.

When the guide input is keyed 1250, the display value is toggled from 1 to 0 or from 0 to 1 1255. When the display value equals 1, representations of the PIV's are displayed on-screen in order to assist the operator in understanding the values of the primary inputs. When the display value equals 0, the representations are not displayed in order to make more room on the screen.

When the set menu input is keyed 1260, the primary inputs become a menu of sets: a selectable new set is assigned to each primary input and the set names are displayed on-screen to assist navigation 1265. When a new set is chosen by keying the corresponding primary input 1270, the first and second PIV's are re-assigned according to the new selected set 1275.

When one of the several hot set inputs is keyed 1280, the first and second PIV's are re-assigned according to the hot set selected 1285. Hot sets are sets that work in conjunction with the selected set, such as a punctuation set and number set working in conjunction with an alphabet set.

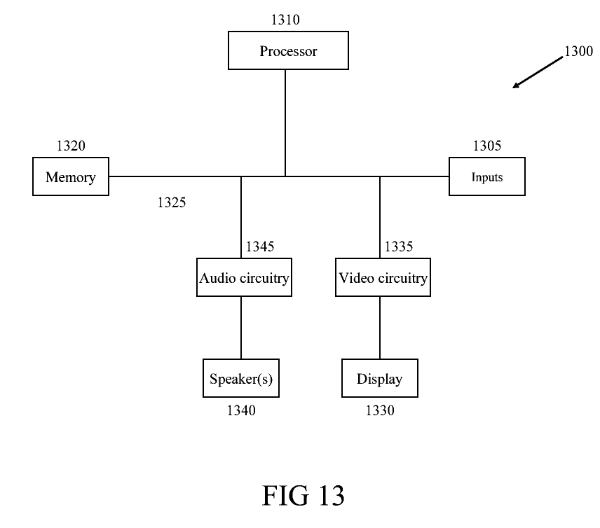

FIG. 13 shows the components 1300 of an electronic device including inputs 1305 in accordance with an embodiment of the present invention. The components 1300 also include a processor 1310 which carries out instructions that implement the algorithms reflected in the flow chart of FIG. 12. The processor 1310 is coupled to memory 1320, which may include random access memory, read only memory, hard drive(s), optical media, and/or a flash device, via a bus 1325. The memory 1320 stores the instructions that implement the algorithms reflected in the flow chart of FIG. 12 and the corresponding data that may be relied upon or produced by those instructions. The processor 1310 is coupled to the inputs 1305 via, for example, the bus 1325, and processes the inputs received therefrom to facilitate carrying out the above referenced instructions. The processor 1310 may also be further coupled to a display 1330 via the bus 1325 and video circuitry 1335. The processor 1310 may also be further coupled to audio components, such as speakers 1340, via audio circuitry 1345. In addition, although the components 1300 of the electronic device may be in a single enclosure, it may be the case that the components 1300 of the electronic device may be included in separate enclosures and coupled to each other wirelessly via, for example, bluetooth or IR based technology, including transmitters and receivers in each enclosure. Alternatively, the components 1300 in each of the enclosures may be coupled via a wire between the enclosures. In this way, for example, the inputs 1305 may be in an ergonomically configured controller, with the remaining components in a separate enclosure.

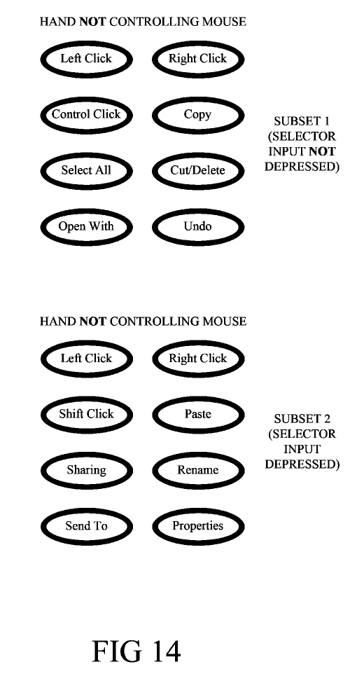

FIG. 14 depicts a ‘half-set’ for controlling the trackball 345. The trackball 345 can be used by either the left or right hand—a setting which can be quickly toggled in the programming set. When the trackball input 350 located beneath or around the trackball 345, is keyed, the trackball 345 becomes active, the trackball pointer appears on the screen 335, and the primary inputs 305 relating to the hand controlling the trackball 345 become inactive. Additionally, the primary inputs 305 relating to the hand not controlling the trackball 345 become a ‘half set’ (one hand only) of inputs that directly relate to trackball control, i.e. [left click] and [right click], as well as other functions which relate to both trackball function and the selected character or function set. For instance, in an alphabet or text navigation set, the trackball controls might include [copy], [paste], [replace with], etc. The trackball 345 could be supplied by a touch pad, a directional pad, an orbiting button, an indented orbiting button, a pressure sensitive ring, or other means.

FIGS. 3, 4, 5, and 6 depict applications of the present invention in a common hand-held device. Examples of such a device include: a PDA, a cellular phone, a hand-held word processor, digital camera, iPod™, internet browser, gaming device, mini-television, or a device which combines some or all of these functions, as well as other possible additional functions.

The present invention may also be implemented in portable computing devices in a wide range of sizes, from very small to tablet size to full laptop size and even larger. This invention eliminates the need for a separate keyboard, which typically doubles the size of any device, and provides an incredible range of potential inputs, expanding the device's potential usefulness many times over. Additionally, implementations of this invention use up very little front-side space on a device, meaning the viewing screen can be nearly as large as the entire height and width of the device itself.

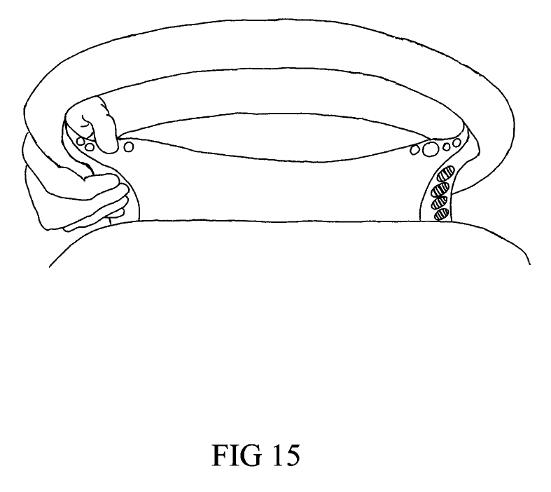

This invention can be applied to any portable computing device, including but not limited to: monitoring equipment, bar code scanners, radios, remote control handsets, scientific calculators, scientific or engineering ‘companions,’ video and sound system controllers, universal household controllers, recording devices—audio and visual, etc., as well as computers in military vehicles, police patrol car computers, airplane onboard computers, etc. With reference to these last three, an application of this invention places the inputs (with a stripped down version of the supplementary inputs) on the controls or steering wheel of the vehicle, so that the pilot or officer need not turn their body or remove their hands from the controls in order to use the computer. This application is depicted in FIG. 15.

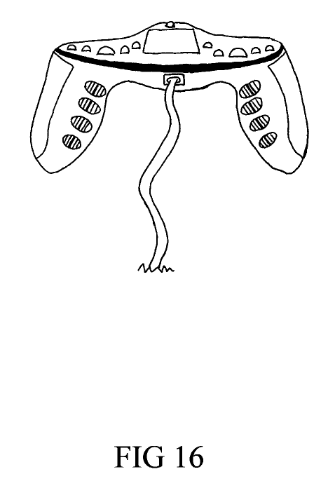

FIG. 16 depicts another application of the present invention: a keyboard-replacement version which attaches to a home computer in the various manners of a traditional QWERTY keyboard, by chord or by various wireless technologies, such as blue tooth. Highly ergonomic in design and similar to a modern video game controller, this keyboard-replacement places all of the muscles of the arms and fingers in their most relaxed and natural positions, especially when the device is cradled in the lap, and requires only minimal finger and thumb movements. These ergonomic factors greatly reduce the risk of repetitive stress injuries such as carpal tunnel syndrome. This application would be ideal when used in conjunction with a ‘virtual reality’ visor or goggles in which the operator cannot see the input keys, making the display of the primary input guides within the virtual scene very practical.

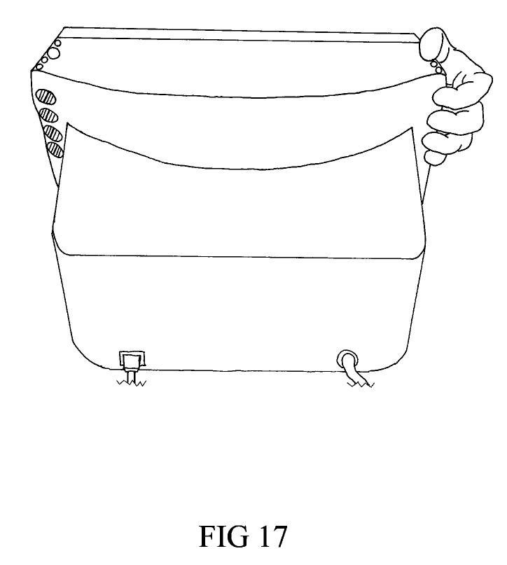

FIG. 17 depicts another application of the present invention: the placement of the inputs on the sides or back of a keyboardless monitor-only unit, such as a touch screen computer in a museum or an ATM in a bank. This would allow the unit to present itself as simply a monitor (or monitor and keypad) to the public, but also give an employee or technician full access to its operating system.

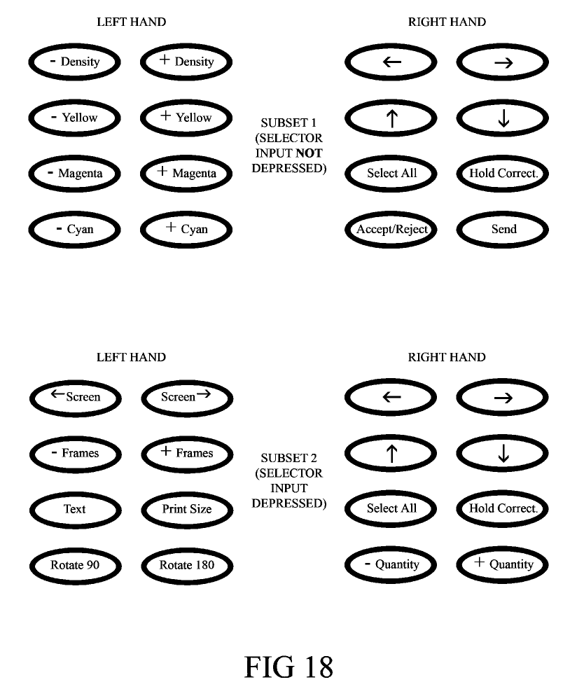

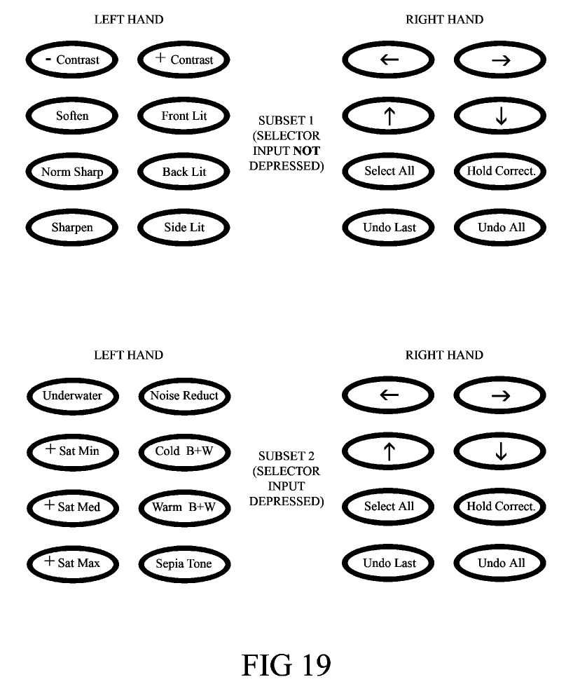

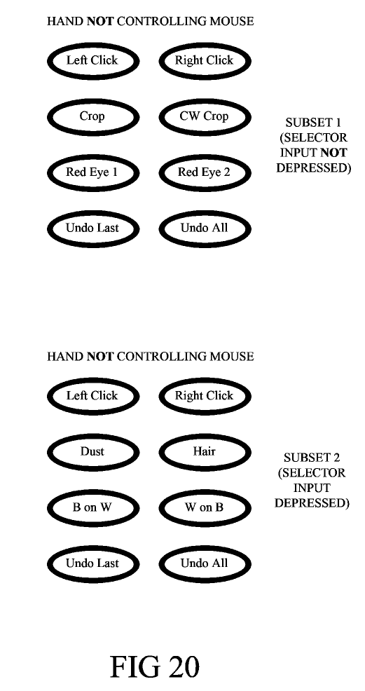

Finally, the input system outlined by the present invention can be applied to any computer, machine, or device that can utilize inputs, providing an ergonomic and comprehensive control system. FIGS. 18, 19, and 20 depict potential sets of primary input designations when the present invention is applied to a production machine, specifically a Noritsu 2711 photo printing machine. This application demonstrates how the present invention can streamline a somewhat ponderous process, eliminating the need for the operator to navigate through a series of supplementary photo correction screens by reducing them to a few sets of instantly accessible inputs.

What is claimed is:

1. An input system for an electronic device comprising:
a plurality of primary inputs that are associated with designated sets of characters and/or functions, wherein
said inputs are placed on at least one or more of a back, side, or bottom of the electronic device and are arranged in pairs of two inputs each such that the fingertips of a majority of an operator's fingers are each aligned with one of said input pairs.

2. The input system of claim 1, further comprising a selector input that changes one or more designations of the primary inputs and that is placed on one of a front, top, or side of the device in alignment with one of the operator's thumbs.

3. The input system of claim 1, wherein at least one of the primary inputs is a three-position momentary rocker switch.

4. The input system of claim 1, further comprising a display, wherein visual representations of said characters or functions designated by the primary inputs are displayed on said display in a manner that spatially mimics the placement of the primary inputs on the back of said electronic device.

5. The input system of claim 1, further comprising a display, wherein a visual representation of a primary input is displayed on said display in a manner that changes visually when that input is keyed.

6. The input system of claim 1, further comprising one or more speakers through which auditory representations of the primary inputs are generated.

7. The input system of claim 1, further comprising at least one supplementary input that causes visual and/or auditory representations of characters or functions designated by the primary inputs to become either active or inactive when said supplementary input is selected by an operator of said input system.

8. The input system of claim 1, further comprising at least one supplementary input which causes one or more of any other inputs to become inactive when said supplementary input is selected by an operator of said input system.

9. The input system of claim 1, wherein said electronic device comprises two components that are coupled to each other, with one of the two components being an ergonomic controller.

10. The input system of claim 1, wherein said input system is configured for use with a virtual reality system.

11. The input system of claim 1, wherein said input system is integrated with vehicle controls.

12. An input system for an electronic device comprising a plurality of primary inputs and a selector input, wherein a complete pre-existing human alphabet of 18-64 letters is available to the operator via said primary inputs through only two different subsets, including a first subset and a second subset, and wherein the first subset comprises at least half of the letters in the alphabet, said first subset being selectably replaceable by the second subset, which comprises the remaining letters of the alphabet that are not included in the first subset, due to the action of said selector input.

13. The input system of claim 12 wherein said sets of letters and additional sets of characters and/or functions are made available to an operator through one or more set menus.

14. The input system of claim 12 wherein the primary inputs are configured to represent one of a menu of sets, a menu of set menus, and a combination of one or more of the following: characters, functions, sets, and set menus.

15. The input system of claim 12 further comprising one or more supplementary inputs that correspond to functions which are in addition to any character or function set that may be implemented by the input system via the primary inputs.

16. The input system of claim 12, wherein the primary inputs are paired up into twos.

17. The input system of claim 16, wherein the primary inputs comprise at least one three-position momentary rocker switch.

18. The input system of claim 12, further comprising a supplementary input which causes at least one of any other inputs to become inactive when said supplementary input is selected by an operator of said input system.

19. The input system of claim 12, wherein said electronic device comprises two components that are coupled to each other, with one of the two components being an ergonomic controller.

20. The input system of claim 12 wherein said input system is integrated with vehicle controls.

21. The input system of claim 12, wherein more than one of the primary inputs are placed on one or more of a back, side, or bottom of the device and are arranged in pairs of two inputs each such that the fingertips of a majority of the operator's fingers are each aligned with one of said input pairs.
